(19) United States
(12) Patent Application Publication
(10) Pub. No.: US 2005/0151260 A1
(43) Pub. Date: Jul. 14, 2005

(54) Interconnection structure for a semiconductor device and a method of forming the same

(76) Inventor: Jong-Jin Na, Gyeonggi-do (KR)

Correspondence Address: MARGER JOHNSON & MCCOLLOM, P.C., 1030 SW MORRISON STREET, PORTLAND, OR, 97205, US

(21) Appl. No.: 11/032,895

(22) Filed: Jan. 10, 2005

(30) Foreign Application Priority Data
Jan. 12, 2004 (KR) 2004-02003

(51) Int. Cl. H01L 21/20; H01L 21/4763; H01L 23/48; H01L 29/40

(52) U.S. Cl. 257/758; 438/622; 438/675; 438/685; 257/763

(57) ABSTRACT

An interconnection structure for a semiconductor device, and a method of forming the same, having a tolerance to high temperature and high speed while not suffering from a problem of a drawing out of a first lower metal pattern. In addition, a second lower metal pattern may be formed, not using a patterning process including a photolithography process, but using a selection etching characteristic instead. Therefore, the second lower metal pattern is self-aligned to the first lower metal pattern, thereby making up for a decrease of a margin in the photolithography process with increasing high integration. As a result, the present invention may be employed to fabricate a semiconductor device to be more highly integrated.

### CROSS REFERENCE TO RELATED APPLICATION

This application claims priority under 35 USC § 119 to a Korean Patent Application No. 2004-02003, filed on Jan. 12, 2004, the contents of which are incorporated herein by reference in their entirety.

### BACKGROUND OF THE INVENTION

1. Field of the Invention

The present invention relates to semiconductor devices and methods of forming the same, and specifically, to an interconnection structure for a semiconductor device and a method of forming the same.

2. Description of the Related Art

In general, semiconductor devices have a plurality of transistors arranged on a substrate. Micro electronic elements including the transistors are electrically connected through interconnections. However, with a high integration of the semiconductor devices, the line widths of the interconnection become increasingly thin. Accordingly, there are many difficulties, such as a photoresist consumption, reducing a misalignment margin, and a reliability failure by a migration in forming the interconnection.

FIGS. 1 to 4 are procedural cross-sectional views illustrating a method of forming an interconnection according to the prior art.

Referring to FIG. 1, a lower interconnection 20 is formed on a semiconductor substrate 10. The lower interconnection 20 is formed using an anisotropic etching process, which uses a predetermined photoresist pattern as an etching mask.

As semiconductor devices become highly integrated, the line widths of the photoresist pattern as well as the lower interconnection 20 decrease. While performing an etching process, the height of the photoresist pattern tends to become relatively low. This induces a consumption of the photoresist (that is, the photoresist is removed in an etching process to form the lower interconnection). If the photoresist used as an etching mask is removed prematurely, an etching profile of an etched resultant becomes inadequate. Accordingly, to prevent this, as shown in FIGS. 1 and 2, a hard mask 30 is generally used as an etching mask in the process of forming the lower interconnection 20.

An interlayer dielectric layer 40 covers a resultant where the lower interconnection 20 and the hard mask 30 are formed. In general, the interlayer dielectric layer 40 is formed of a CVD silicon oxide (Chemical Vapor Deposition silicon oxide). Accordingly, as shown in FIG. 1, an upper surface of the interlayer dielectric layer 40 may be formed unconformally. To overcome any problems due to unconformality in subsequent processes, the interlayer dielectric layer 40 is etched using a planarizing etching method such as CMP (Chemical Mechanical Polishing) to form a planarized interlayer dielectric layer 40′ (see FIG. 2). The planarizing etching method is performed so as not to expose an upper surface of the hard mask 30.

Then, the planarized interlayer dielectric layer 40′ and the hard mask 30 are patterned to form an interlayer dielectric pattern 45 and a hard mask pattern 35 (see FIG. 3). The interlayer dielectric layer 45 and the hard mask pattern 35 form via holes 50 that expose a predetermined region of the lower interconnection 20. However, less line width of the lower interconnection 20 leads to less misalignment margin of a patterning process of forming the via hole 50. As a result, technical problems have increased in the patterning process of forming the via hole 50.

After forming via plugs 60 filling the via holes 50, an upper interconnection 70 connecting the via plugs 60 is formed (see FIG. 4).

In another approach, the interconnection is generally formed of aluminum for high-speed semiconductor devices. But, the aluminum interconnection has difficulties with reliability failures such as EM (Electro Migration) or SM (Stress Migration).

### SUMMARY

In one embodiment of the present invention, a method of forming an interconnection for a semiconductor device is provided, which includes forming a lower metal pattern using a selectivity etching characteristic. The method comprises: forming a plurality of lower patterns each comprising a first lower metal pattern and a capping pattern, in which the first lower metal pattern and the capping pattern are sequentially stacked on a semiconductor substrate; forming a lower interlayer dielectric pattern to fill a space between the plurality of lower patterns; forming a trench, which removes the capping pattern to expose the first lower metal pattern; and forming a second lower metal pattern to fill the trench.

Preferably, the capping pattern is used as an etching mask to form the first lower metal pattern in the step of forming the lower patterns. Describing in more detail, forming the lower patterns may comprise: sequentially forming a first lower metal layer and a capping layer on the semiconductor substrate; and patterning the capping layer to form the capping pattern; and anisotropically etching the first lower metal layer using the capping pattern as an etching mask.

### BRIEF DESCRIPTION OF THE DRAWINGS

FIGS. 1 to 4 are procedural cross-sectional views illustrating a method of forming an interconnecting method according to a conventional art.

FIGS. 5 to 10 are procedural cross-sectional views illustrating a method of forming an interconnecting method according to an embodiment of the present invention.

FIGS. 11 to 15 are procedural cross-sectional views illustrating a method of forming an interconnection according to another embodiment of the present invention.

FIG. 16 is a perspective view showing an interconnection structure according to one embodiment of the present invention.

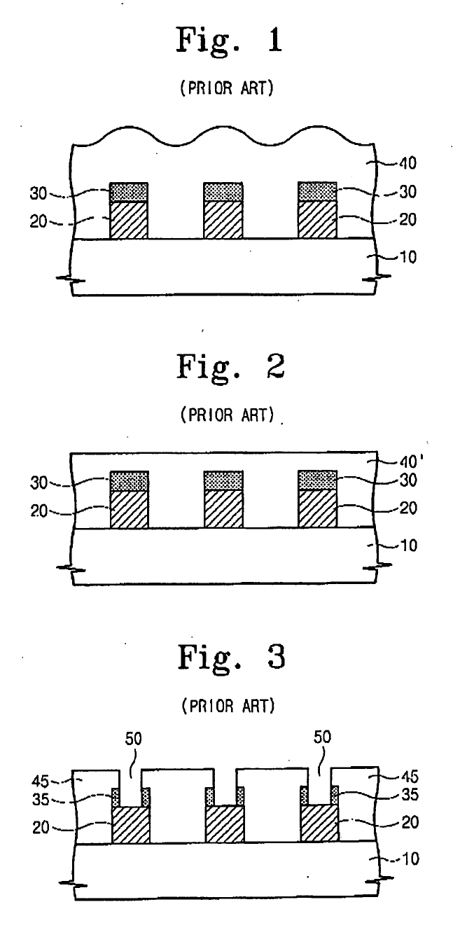

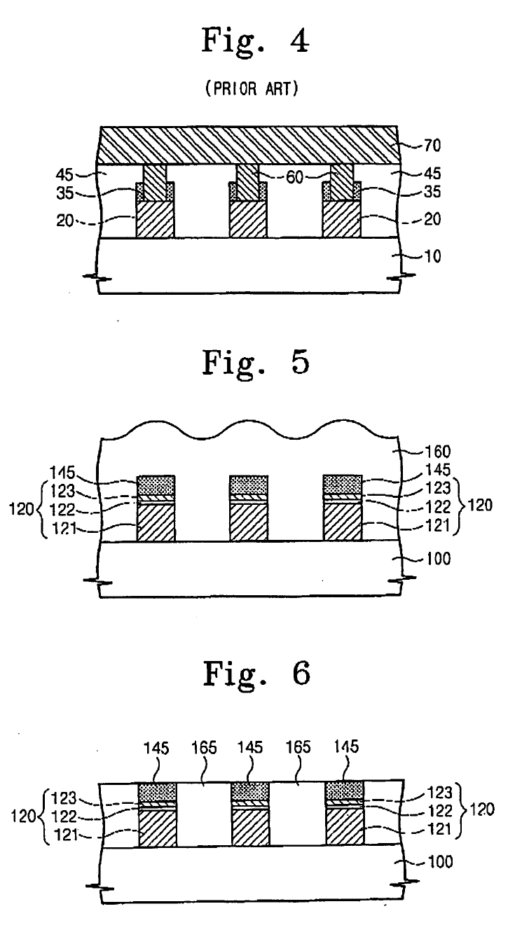

### DETAILED DESCRIPTION OF THE PREFERRED EMBODIMENTS

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present. Like numbers refer to like elements throughout the specification.

FIGS. 5 to 10 are cross-sectional views illustrating a method of forming an interconnecting method according to an embodiment of the present invention.

Referring to FIG. 5, a plurality of lower patterns are formed on a semiconductor substrate 100, and then a lower interlayer dielectric layer 160 is formed on the plurality of lower patterns. The lower interlayer dielectric layer 160 may fill a space between the plurality of lower patterns. The lower pattern comprises a first lower metal pattern 120 and a capping pattern 145, which are sequentially stacked. The first lower metal pattern 120 may be formed of an aluminum pattern 121, a titanium pattern 122 and a titanium nitride pattern 123, which are sequentially stacked.

The lower pattern is formed by patterning the capping layer to form a capping pattern 145 after sequentially forming the first lower metal pattern and a capping layer. A first lower metal layer is patterned using the capping pattern 145 as an etching mask to form the first lower metal pattern 120. Accordingly, it is possible to prevent an inadequate etching profile due to a photoresist consumption as stated earlier regarding the prior art. In addition, since the capping pattern 145 is used as an etching mask, the shape of the capping pattern 145 is transferred to the first lower metal pattern 120. As a result, the first lower metal pattern 120 and the capping pattern 145 have the same line width.

The first lower metal layer may be formed of at least one selected from the group consisting of an aluminum layer, a titanium layer, and a titanium nitride layer. As mentioned above, the first lower metal layer comprises the aluminum layer, the titanium layer and the titanium nitride layer, which are sequentially stacked. The titanium nitride pattern 123 as a resultant may be used as a reflection prevention layer to prevent scattered refection in a photolithography process that forms the first lower metal pattern 120. In addition, the titanium pattern 122 may be used a diffusion prevention layer to prevent increasing contact resistance induced by reacting the titanium nitride layer with the aluminum layer. In this aspect, if the titanium nitride layer and the titanium layer perform a function of a reflection prevention layer, as well as the diffusion prevention layer, different kinds of materials may be available. According to an aspect of the present invention, the aluminum is formed with a thickness of about 2000 to 6000 Å. The titanium layer is formed with a thickness of about 50 to 300 Å. The titanium nitride layer is formed with a thickness of about 100 to 800 Å.

It is preferable that the lower interlayer dielectric layer 160 be formed of insulation materials such as silicon oxide. It is preferable that the capping layer be formed of insulation materials having an etch selectivity with respect to the first lower metal layer and the lower interlayer dielectric layer 160. In other words, it is preferable that the capping layer be formed of insulation materials that may be selectively removed without etching the first lower metal layer and the lower interlayer dielectric layer 160, in a predetermined recipe. In accordance with an embodiment of the present invention, the capping layer may be formed of silicon nitride.

Since the lower interlayer dielectric layer 160 is formed by a deposition process, topography of the lower patterns may be transferred to the lower interlayer dielectric layer 160. Accordingly, an upper surface of the lower interlayer 160, as shown in FIG. 5, becomes bumpy.

Referring to FIG. 6, the lower interlayer dielectric layer 160 is etched until the capping pattern 145 is exposed. Accordingly, a lower interlayer dielectric pattern 165 having a flat upper surface is formed between the lower patterns. To form the lower interlayer dielectric pattern 165, it is preferable that an etching process is performed using a CMP method. For this reason, an upper surface of the lower interlayer dielectric pattern 165 has substantially the same height as upper portions of the capping patterns 145.

Unlike the conventional art, an etching process to form the lower interlayer dielectric pattern 165 is performed so as to expose the capping pattern 145. Accordingly, as more fully described hereinafter, an etching process to form the first lower metal pattern 120 may be performed using an etch selectivity without a photolithography process.

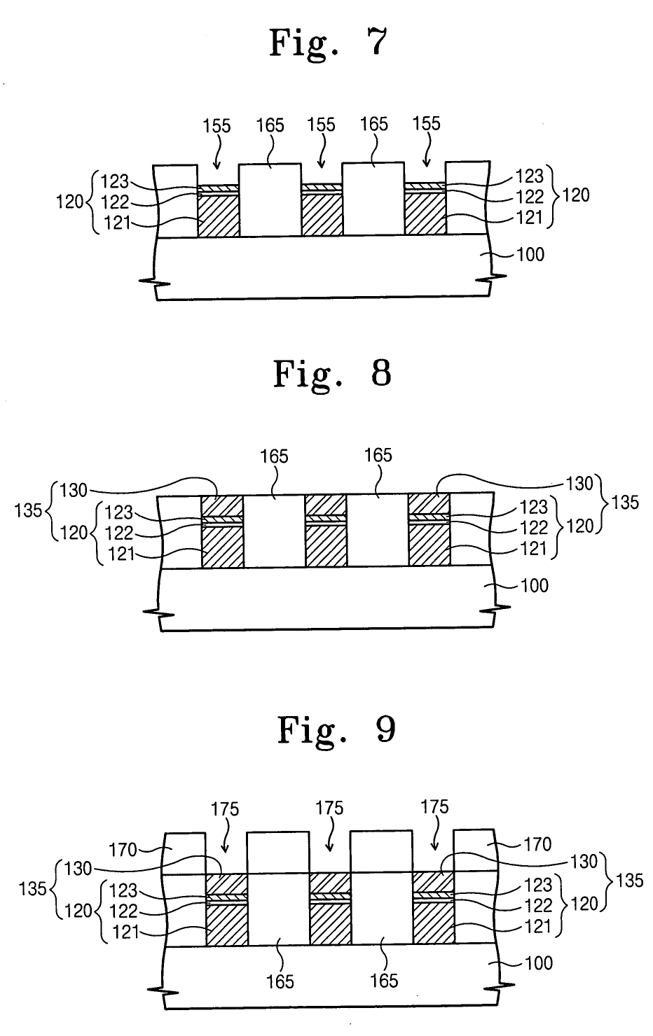

Referring to FIG. 7, the exposed capping patterns 145 are removed to expose an upper surface of the first lower metal pattern 120. As a result, a trench 155 exposing the upper portion of the first lower metal pattern 120 is formed between the lower interlayer dielectric patterns 165.

The capping patterns 145 may be removed using an isotropic etching process, preferably, a wet etch process. Accordingly, it is possible to prevent the lower interlayer dielectric pattern 165 and the first lower metal pattern 120 from etching damages due to plasma. The lower interlayer dielectric pattern 165 and the first lower metal pattern 120 are composed of inner sidewalls of the trench 155.

At this time, the step of removing the capping patterns 145 does not use an etching mask additionally formed through a photolithography process but instead uses a selection etching characteristic between the capping pattern 145 and the lower interlayer dielectric layer 160. Therefore, it is possible to minimize producing inferior results related with asymmetry, which may be induced by a misalignment in the photolithography process. That is, the trench 155 is self-aligned to the first lower metal pattern 120.

Referring to FIG. 8, a second lower metal layer is formed on an entire surface of a resultant where the trench 155 is formed. The second lower metal layer uses one of metal materials having a high melting point or a low resistivity. For example, the second lower metal layer may include at least one of tungsten, cobalt, titanium, titanium nitride and copper. In addition, chemical vapor deposition, physical vapor deposition or electroplating may be available in the step of forming the second lower metal layer.

While the lower interlayer dielectric pattern 165 is exposed, the second lower metal layer is planarized by etching. Accordingly, a second lower metal pattern 130 filling the trench 155 is formed. Resultantly, the second lower metal pattern 130 fills a space where the capping pattern 145 was removed, that is, the trench 155.

Together, the first lower metal pattern 120 and the second lower metal pattern 130 compose a lower metal pattern 135. At this time, it is preferable that the second lower metal pattern 130 is formed of materials capable of preventing a migration. In this case, it is possible to prevent the first lower metal pattern 120 from being drawn out by migration. In addition, as state above, if the second lower metal pattern 130 is formed of a high melting temperature or a low resistivity, an interconnection structure having a tolerance to high temperature and high speed may be formed.

Referring to FIG. 9, an upper interlayer dielectric layer 170 covers an entire surface of a resultant where the second lower metal pattern 130 is formed. The upper interlayer dielectric layer 170 is patterned to form via holes 175, exposing an upper surface of the second lower metal pattern 130.

The upper interlayer layer 170 may be formed of at least one selected from the group consisting of silicon oxide, silicon nitride, silicon oxynitride, silicon carbide, and SOG. In particular, to prevent etching damage to the lower interlayer dielectric pattern 165 in a patterning process to form the via hole 175, the upper interlayer dielectric layer 170 may include an insulation layer having an etch selectivity with respect to the lower interlayer dielectric layer 165. In this case, it is preferable that an etch stop layer is composed of the lowest layer of the upper interlayer dielectric layer 170 and is in contact with an upper surface of the lower interlayer dielectric pattern 165.

An etching process to form the via hole 175 may use a photoresist pattern formed by a predetermined etching process and in general, uses an isotropic etch process. At this time, the height of the lower metal pattern 135 becomes as high as the height of the second lower metal pattern 130, so that an etching process to form the via hole 175 has a margin for an over-etch. By increasing the margin for the over-etch, a misalignment margin is increased in a process to form the via hole 175. As a result, as shown in FIG. 9, the width of the via hole 175 may be wider than the line width of the second lower metal pattern 130.

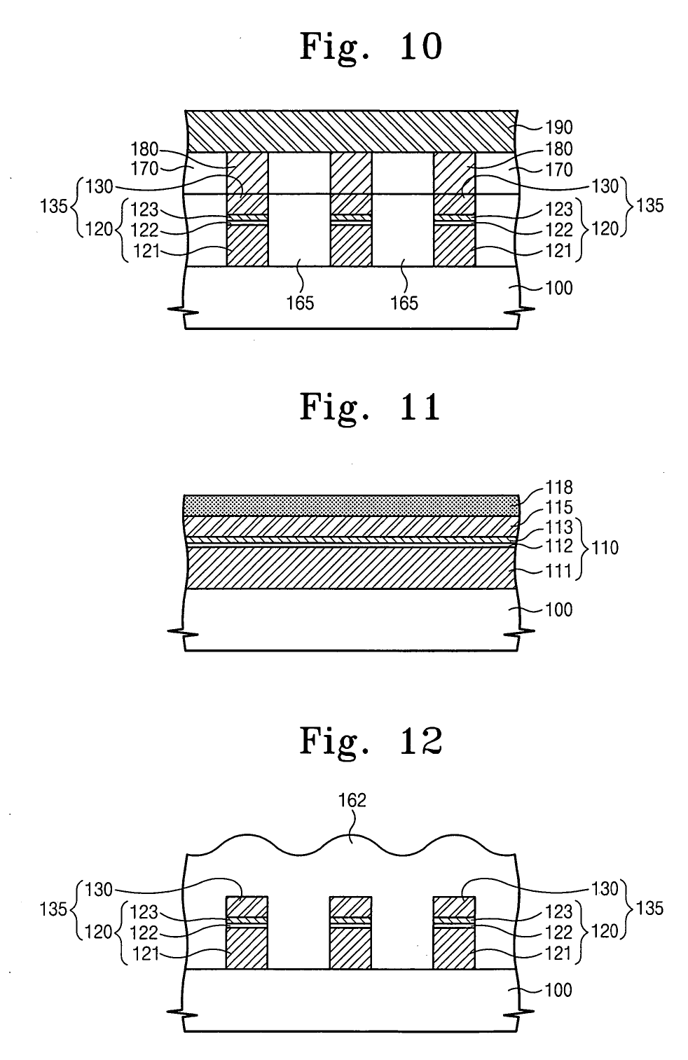

Referring to FIG. 10, after forming via plugs 180 that fill the via holes 175, an upper metal pattern 190 connecting the via plugs 180 is formed.

The step of forming the via plugs 180 includes the steps of forming a plug conductive layer covering an entire surface of a resultant where the via holes 175 are formed, and planarizing the plug conductive layer until an upper surface of the upper interlayer dielectric layer 170 is exposed. It is preferable that the planarizing etching process is performed using a chemical mechanical polishing process. In addition, the plug conductive layer is formed of at least one selected from the group consisting of tungsten, titanium, titanium nitride, and copper.

The upper metal pattern 190 electrically connects the lower metal pattern 135 through the via plugs 180. Additionally, the via plugs 180 may be formed of the same material as the upper metal pattern 190. For this, a wiring process patterning the plug conductive layer to form the upper metal pattern without the planarizing etching process may be available.

FIGS. 11 to 15 are procedural cross-sectional views showing a method of forming an interconnection according to another embodiment of the present invention. In this embodiment, the second lower metal pattern 130 is formed using a patterning process, in contrast to using selection etching between the capping pattern 145 and the lower interlayer dielectric pattern 165. Now, the same descriptions as those in the previous embodiment are omitted hereinafter for brevity.

Referring to FIGS. 11 and 12, a first lower metal layer 110, a second lower metal layer 115, and a capping layer 118 are sequentially formed on a semiconductor substrate 100. Preferably, the first lower metal layer 110 may be formed of an aluminum layer 111, a titanium layer 112, and a titanium nitride layer 113, which are sequentially stacked. As shown in FIG. 5, the titanium layer 112 and the titanium nitride layer 113 may be replaced by another metal layer capable of performing a function as a reflection prevention layer and a diffusion prevention layer.

The capping layer 118 is patterned to form a capping pattern to define a lower metal pattern 135. The first and second lower metal layers 110 and 115 are sequentially etched using the capping pattern as an etching mask to form a lower metal pattern 135. The lower metal pattern 135 comprises the first lower metal pattern 120 and the second lower metal pattern 130, which are sequentially stacked. The capping pattern, as shown in FIG. 12, may be removed by an etching process to form the lower metal pattern 135 or an additional etching process. After that, an interlayer dielectric layer 162 is deposited on an entire surface of a resultant where the lower metal pattern 135 is formed.

At this time, the second lower metal layer 115 may be formed of at least one of metal materials having a high melting point or a low resistivity (e.g., tungsten, cobalt, titanium, titanium nitride and copper). In addition, chemical vapor deposition, physical vapor deposition or electroplating may be available in the processing step of forming the second lower metal layer 15. Furthermore, it is preferable that the second lower metal pattern 115 be formed of materials capable of preventing a migration. In this case, it is possible to prevent the first lower metal pattern 120 from being drawn out by migration.

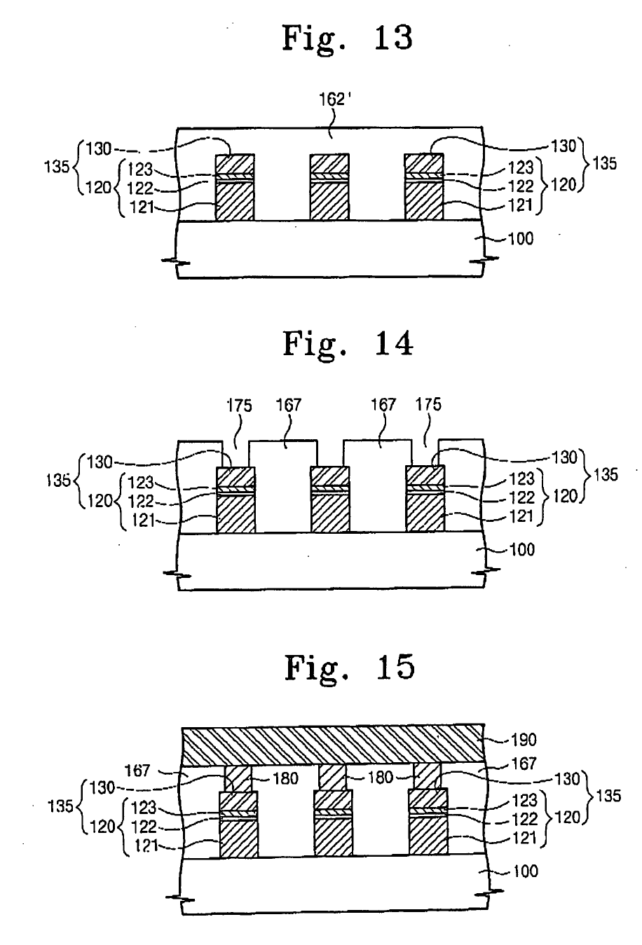

Referring to FIG. 13, a planarized interlayer dielectric layer 162′ may be formed by planarizing the interlayer dielectric layer 162. The planarizing etching may be performed using a chemical mechanical polishing method. In another approach, according to this embodiment, the via hole as shown in FIG. 9 is formed on the planarized interlayer dielectric layer 162′, so that it is preferable that the height of an upper surface of the planarized interlayer dielectric layer 162′ is higher than that of the second lower metal pattern 130. In other words, it is preferable that the planarizing etching process is performed so as not to expose an upper surface of the second lower metal pattern 130.

Referring to FIGS. 14 and 15, the planarized interlayer dielectric layer 162′ is patterned to form an interlayer dielectric layer 167 having via holes 175 exposing an upper surface of the second lower metal pattern 130. A patterning process to form the via hole 175 includes a predetermined photolithography step and an anisotropic etching process.

After that, an upper metal pattern 190 connecting to via plugs 180 that fill the via holes 175 is formed. The description regarding the previous embodiment is applicable to this process, and additional description is therefore omitted.

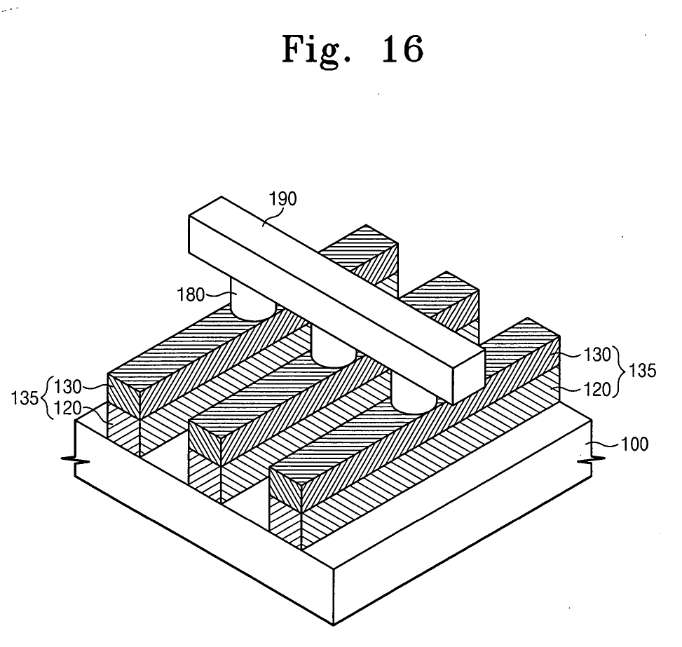

FIG. 16 is a perspective view showing an interconnection structure according to the present invention.

Referring to FIG. 16, the interconnection structure according to an embodiment of the present invention may be a plurality of lower metal patterns 135 arranged on a semiconductor substrate 100. An upper metal pattern 190 is arranged on an upper surface of the lower metal patterns 135. The upper metal patterns 135 are electrically connected through predetermined via plugs 180 to the lower metal pattern 135.

At this time, the lower metal pattern 135 comprises a first lower metal pattern 120 and a second lower metal pattern 130, which are sequentially stacked. The first lower metal pattern 120 is formed of at least one selected from the group consisting of an aluminum layer, a titanium layer, and a titanium nitride layer.

The line width of the second lower metal pattern 130 may be the same as or wider than that of the first lower metal pattern 120. If the line width of the second lower metal pattern 130 is wider than that of the first lower metal pattern 120, the protruded width of the second lower metal pattern 120 is the same on both sides. That is, the lower metal pattern 135 has a symmetric cross section with respect to either side. This symmetric cross section may be shown in a whole region of the semiconductor device.

The second lower metal pattern 130 may be formed of at least one of metal materials having a high melting point or a low resistivity (e.g., tungsten, cobalt, titanium, titanium nitride, and copper). Accordingly, the lower metal pattern 135 has a tolerance to high temperature and high speed.

Furthermore, it is preferable that the second lower metal layer 115 is formed of metal materials capable of preventing a migration. In this case, it is possible to prevent the first lower metal pattern 120 from being drawn out by migration.

Although not shown, an interlayer dielectric layer supporting and insulating the interconnections is interposed between the lower metal patterns 135, and between the upper metal patterns 190 and the via plugs 180 (see 165 and 170 in FIG. 10, and 167 in FIG. 15).

According to an aspect of the present invention, a lower metal pattern with a sequentially stacked structure of first and second lower metal patterns is formed. At this time, the second lower metal pattern may be formed of metal materials capable of preventing a migration, having a high melting point or having a low resistivity. Accordingly, it is possible to produce semiconductor products having a tolerance to high temperature and high speed while not suffering from a problem of a drawing out of the first lower metal pattern.

In addition, the second lower metal pattern may be formed not using a patterning process including a photolithography process, but using a selection etching characteristic. Therefore, the second lower metal pattern is self-aligned to the first lower metal pattern, thereby making up for a decrease of a margin in the photolithography process with increasing high integration. As a result, the present invention may be employed to fabricate a semiconductor device to be more highly integrated.

Having illustrated and described the principles of my invention in a preferred embodiment thereof, it should be readily apparent to those skilled in the art that the invention can be modified in arrangement and detail without departing from such principles. We claim all modifications coming within the spirit and scope of the accompanying claims.

1. A method of interconnecting a semiconductor device comprising:
forming a plurality of lower patterns, each comprising a first lower metal pattern and a capping pattern, the first lower metal pattern and the capping pattern being sequentially stacked on a semiconductor substrate;
forming a lower interlayer dielectric pattern to fill a space between the plurality of lower patterns;
forming a trench that removes the capping pattern to expose the first lower metal pattern; and
forming a second lower metal pattern to fill the trench.

2. The method of claim 1, wherein the capping pattern is used as an etching mask to form the first lower metal pattern in the formation of the plurality of lower patterns.

3. The method of claim 2, wherein forming the plurality of lower patterns comprises:
sequentially forming a first lower metal layer and a capping layer on the semiconductor substrate; and
patterning the capping layer to form the capping pattern; and
anisotropically etching the first lower metal layer using the capping pattern as an etching mask.

4. The method of claim 1, wherein the first lower metal pattern may be formed of at least one selected from the group consisting of aluminum, titanium, and titanium nitride.

5. The method of claim 1, wherein the second lower metal pattern is formed of at least one selected from the group consisting of tungsten, cobalt, titanium, titanium nitride, and copper.

6. The method of claim 1, wherein the capping pattern is formed of a material having an etching rate at least ten times faster than that of a material of which the lower interlayer dielectric pattern comprises in a predetermined etch recipe.

7. The method of claim 1, wherein the capping pattern is formed of at least one selected from the group consisting of silicon nitride, silicon oxynitride, and silicon oxide.

8. The method of claim 1, wherein forming the lower interlayer dielectric pattern comprises:
forming a lower interlayer dielectric layer on the plurality of lower patterns; and
planarizing the lower interlayer dielectric layer to expose an upper surface of the capping pattern.

9. The method of claim 1, wherein forming the trench includes selectively removing the capping pattern.

10. The method of claim 9, wherein selectively removing the capping pattern is performed using an isotropic etching method including a wet etch method.

11. The method of claim 1, wherein the forming the second lower metal pattern comprises:
forming a second lower metal layer overlying the trench; and
planarizing the second lower metal layer until the lower interlayer dielectric pattern is exposed.

12. The method of claim 1, further comprises, after forming the second lower metal pattern:
forming an upper interlayer dielectric pattern having via holes exposing the second lower metal pattern;
forming a via plug filling the via holes; and
forming an upper metal pattern, which is arranged on the upper interlayer dielectric pattern to connect the via plugs.

13. A method of interconnecting a semiconductor device comprising:
forming a plurality of lower metal patterns each comprising a first lower metal pattern and a second lower metal pattern, the first and the second lower metal patterns being sequentially stacked on a semiconductor substrate;
forming an interlayer dielectric layer on the plurality of lower metal patterns;
forming a via plug to penetrate the interlayer dielectric layer; and
forming an upper metal pattern connected to an upper surface of the plurality of lower metal patterns by the via plug,
wherein the second lower metal pattern has a line width that is the same or larger than that of the first lower metal pattern.

14. The method of claim 13, wherein the first lower metal pattern is formed of at least one selected from the group consisting of aluminum, titanium, and titanium nitride, and
wherein the second lower metal pattern is formed of at least one selected from the group consisting of tungsten, cobalt, titanium, titanium nitride, and copper.

15. The method of claim 13, wherein the forming the via plug comprises:
planarizing the interlayer dielectric layer;
patterning the planarized interlayer dielectric layer to form a via hole to expose an upper surface of the second lower metal pattern;
forming a plug conductive layer to fill the via hole; and
planarizing the plug conductive layer until the planarized interlayer dielectric layer is exposed,
wherein the planarizing the interlayer dielectric layer is performed so as not to expose the upper surface of the second lower metal pattern.

16. An interconnecting semiconductor device comprising:
a plurality of lower metal patterns each comprising a first lower metal pattern and a second lower metal pattern, the first and the second lower metal patterns being sequentially stacked on a semiconductor substrate;
an upper metal pattern on the plurality of lower metal patterns; and
via plugs to connect the upper metal pattern and the plurality of lower metal patterns.

17. The interconnecting semiconductor device of claim 16, wherein the plurality of lower metal patterns each have a symmetric cross section.

18. The interconnecting semiconductor device of claim 16, wherein the plurality of lower metal patterns have a symmetric cross section in at least a portion of the semiconductor substrate.

19. The interconnecting semiconductor device of claim 16, wherein the first lower metal pattern is formed of at least one selected from the group consisting of aluminum, titanium, and titanium nitride, and
wherein the second lower metal pattern is formed of at least one selected from the group consisting of tungsten, cobalt, titanium, titanium nitride, and copper.

20. The interconnecting semiconductor device of claim 16, further comprising a lower interlayer dielectric pattern arranged between each of the plurality of lower metal patterns, wherein an upper surface of the lower interlayer dielectric pattern and each of the plurality of lower metal patterns have substantially the same height.
